(19) United States
(12) Patent Application Publication
(10) Pub. No.: US 2026/0068174 A1
(43) Pub. Date: Mar. 5, 2026

(54) OVERHANG ARCHITECTURES FOR HIGH BANDWIDTH MEMORY (HBM) MULTI-DIE ASSEMBLIES AND METHODS FOR MAKING SAME

(71) Applicant: Intel Corporation, Santa Clara, CA (US)

(72) Inventors: Seok Ling Lim, Bukit Mertajam (MY); Eng Huat Goh, Ayer Itam (MY)

(73) Assignee: Intel Corporation, Santa Clara, CA (US)

(21) Appl. No.: 18/819,209

(22) Filed: Aug. 29, 2024

(51) Int. Cl. H10B 80/00; H01L 25/00; H01L 25/065; H01L 25/18

(52) U.S. Cl. CPC H10B 80/00

(57) ABSTRACT

Overhang architectures for high bandwidth memory (HBM) multi-die assemblies and methods for making same. The overhang architecture places the DRAM (HBM) underneath the top IC die. The signal interconnects between the top IC die and the DRAM die are direct signal interconnects without lateral routing on a package substrate or on a motherboard.

### BACKGROUND

Some contemporary applications, such as artificial intelligence (AI) require memory devices to operate at fast operating frequencies (also called high memory bandwidth). Achieving the necessary high memory bandwidth is a technical challenge for the overall packaging architecture. Accordingly, continued improvements to high memory bandwidth packaging architectures are desirable.

### BRIEF DESCRIPTION OF THE DRAWINGS

FIG. 1A is a simplified top-down view of a system that implements the overhang architecture described herein.

FIG. 1B is a simplified cross-sectional view of the system of FIG. 1A, illustrating aspects of the overhang architecture described herein.

FIG. 2 illustrates an exemplary high bandwidth memory (HBM), in accordance with various embodiments disclosed herein.

FIGS. 3A, 3B, 3C, 4A, and 4B are simplified illustrations depicting various stages of assembly of exemplary embodiments, as disclosed herein.

FIG. 5 depicts an exemplary system or product that can be based on embodiments disclosed herein.

FIG. 6 illustrates an example method for manufacturing and assembling various embodiments disclosed herein.

FIG. 7 illustrates an exemplary system that includes embodiments disclosed herein.

FIG. 8 is a top view of a wafer and dies that may be included in a microelectronic assembly, in accordance with any of the embodiments disclosed herein.

FIG. 9 is a simplified cross-sectional side view showing an implementation of an integrated circuit on a die that may be included in various embodiments, in accordance with any of the embodiments disclosed herein.

FIG. 10 is a cross-sectional side view of a microelectronic assembly that may include any of the embodiments disclosed herein.

FIG. 11 is a block diagram of an example electrical device that may include any of the embodiments disclosed herein.

### DETAILED DESCRIPTION

Some contemporary applications, such as artificial intelligence (AI) require memory devices to operate at fast operating frequencies (also called high memory bandwidth). Achieving the necessary memory bandwidth is a technical challenge for the overall packaging architecture and has moved the memory components from separately packaged memory chips/modules to stacked silicon memory dies called high bandwidth memory (HBM).

Some available solutions place an HBM on a package substrate or on a base die (wherein “base die” means a first silicon die and can be active or passive) and rely on an interposer or embedded bridge component to route signals between the HBM and other integrated circuit (IC) dies, such as a CPU or an SOC. However, even with the embedded bridge component approach, technical challenges remain to achieving the desired high memory bandwidth.

A first technical challenge is that the scaling and pitch for the embedded bridge component cannot be less than about 45 microns (wherein “about” means plus or minus 10%). Further scaling can be limited by the technology of the substrate fabrication.

Another technical challenge is associated with the length of the interconnect traces or paths between the HBM and the IC die. As multi-die assemblies and systems get larger, the extended package size translates to extended interconnect lengths. The length of the interconnect affects the signal latency, and this is more problematic at faster/higher frequencies.

Embodiments disclosed herein propose a technical solution to the above-described technical problems in the form of overhang architectures for high bandwidth memory (HBM) multi-die assemblies and methods for making same. Embodiments advantageously enable a packaging architecture in which HBM components are directly electrically coupled to a “top die” (the top die being an IC die attached on top of the base die) such that signals between the HBM component and top die have direct connections, without routing through the base die or through the package substrate. Embodiments require that a top-most memory die in the HBM component includes through-silicon vias (TSV) that are open to the top surface; the TSVs are for signal connections and for power connections that can be supplied from the package substrate, such as via controlled collapse chip connection (C4) flip-chip bumps. The top die has the overhang architecture, the overhang architecture is characterized by (or defined by) an area extension of the top die (past the base die) that includes dedicated conductive contacts for interconnects to the TSV exposed t the top surface of the HBM component. The provided embodiments enable more compact systems, devices, and products that perform with the required high memory bandwidth of cutting-edge applications such as those that use AI. These concepts are developed in more detail below.

Example embodiments are hereinafter described in conjunction with the following drawing figures, wherein like numerals denote like elements. Figures are not necessarily to scale but may be relied on for spatial orientation and relative positioning of features. As may be appreciated, certain terminology, such as “ceiling” and “floor,” as well as “upper,” “uppermost”, “lower,” “above,” “below,” “bottom,” and “top” refer to directions based on viewing the Figures to which reference is made. Further, terms such as “front,” “back,” “rear,”, “side”, “vertical”, and “horizontal” may describe the orientation and/or location of portions of the component within a consistent but arbitrary frame of reference which is made clear by reference to the text and the associated Figures describing the component under discussion. Such terminology may include the words specifically mentioned above, derivatives thereof, and words of similar import.

As used herein, the term “adjacent” refers to layers or components that are in direct physical contact with each other, with no layers or components in between them. For example, a layer X that is adjacent to a layer Y refers to a layer that is in direct physical contact with layer Y. In contrast, as used herein, the phrase(s) “located on” (in the alternative, “located under,” “located above/over,” or “located next to,” in the context of a first layer or component located on a second layer or component) includes (i) configurations in which the first layer or component is directly physically attached to the second layer (i.e., adjacent), and (ii) component and configurations in which the first layer or component is attached (e.g. electrically coupled) to the second layer or component via one or more intervening layers or components.

As used herein, the term “electronic component” can refer to an active electronic circuit (e.g., processing unit, memory, storage device, FET) or a passive electronic circuit (e.g., resistor, inductor, capacitor).

The following detailed description is not intended to limit the application and use of the disclosed technologies. It may be evident that the novel embodiments can be practiced without every detail described herein. For the sake of brevity, well-known structures and devices may be shown in block diagram form to facilitate a description thereof.

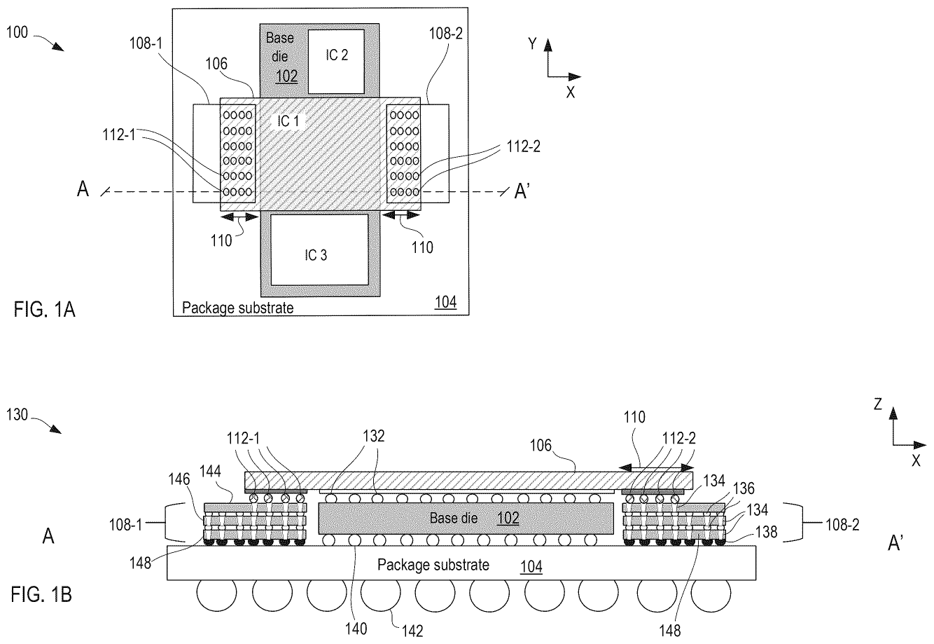

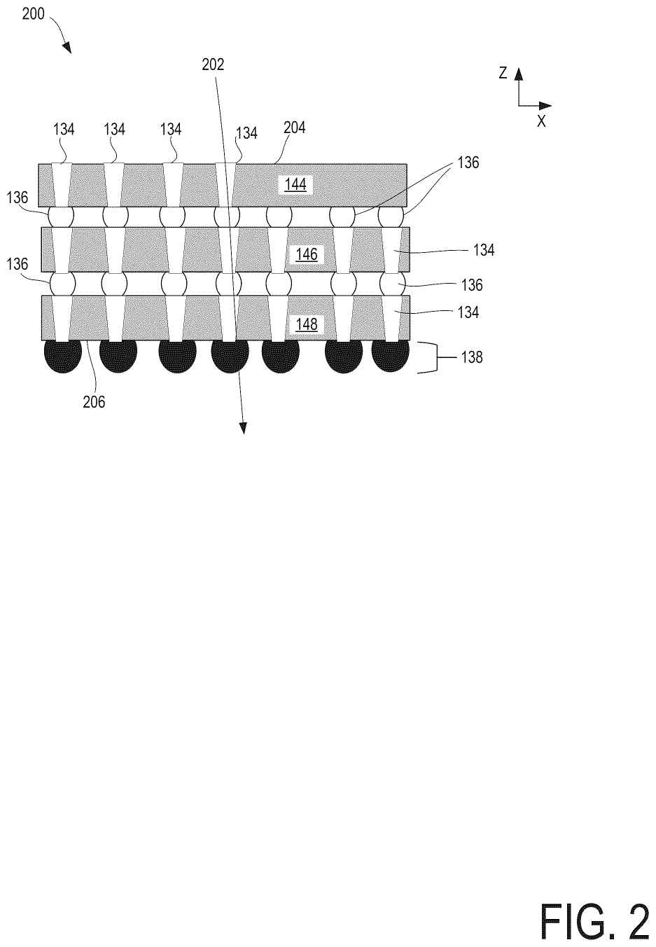

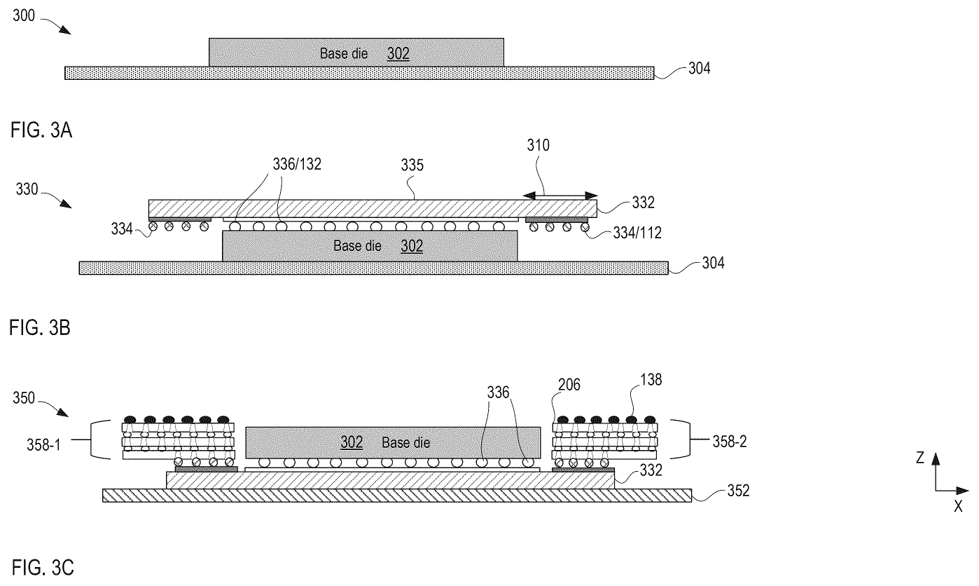

FIG. 1A and FIG. 1B provide two simplified views of an exemplary system or multi-die assembly that implements the overhang architecture described herein. FIG. 1A is a top-down, or plan view 100, and FIG. 1B is a cross-sectional view 130. In FIG. 2, an expanded view 200 illustrates the exemplary high bandwidth memory (HBM) (HBM 108-1, HBM 108-2), as implemented by embodiments described herein.

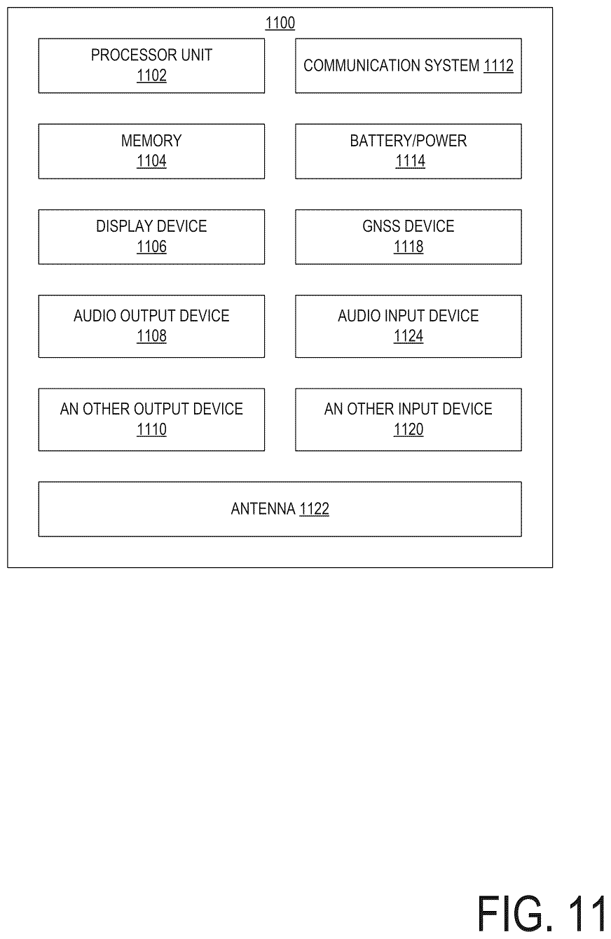

As mentioned above, the base die 102 comprises silicon and functions as an interposer, providing routing and connections for the IC dies (IC 1, IC 2, IC 3, etc.) which are operably connected thereto, e.g., by a solder attach. The base die 102/interposer die can be active or passive and is sometimes called a first integrated circuit die for that reason. The base die 102 has at least one integrated circuit (IC) die attached to its upper surface. As used herein, the term “integrated circuit” or “integrated circuit component” can refer to an electronic component configured on a semiconducting material to perform a function. An integrated circuit (IC) can comprise one or more of any computing system components described or referenced herein or any other computing system component, such as a processor unit (see, e.g., FIG. 11 discussion for processor unit 1102 definition), I/O controller, memory, or network interface controller, and can comprise one or more additional active or passive devices such as capacitors, decoupling capacitors, resistors, inductors, fuses, diodes, transformers, sensors, electrostatic discharge (ESD) devices, and memory devices.

As used herein, an “IC die” references an unpackaged integrated circuit component, such as a single monolithic integrated circuit die (also shortened herein to “die”); the die may include solder bumps attached to contacts on the die. The IC die includes conductive contacts that can be directly attached to another component via interconnects arranged on and electrically coupled to the conductive contacts In view 100, at least IC 1 (IC 106) die is attached to an upper surface of the base die 102; in the exemplary illustration, IC 2 die and IC 3 die are also depicted as being attached to the upper surface of the base die 102. The at least one IC die (IC 106) includes the overhang architecture.

The overhang architecture comprises at least one extension of the IC 106 die past the external periphery of the base die (alternatively, an overhang portion extends beyond a horizontal extent of the first IC die/base die 102); individual extensions are of sufficient width 110 to include a region of conductive contacts that are dedicated input/output (I/O 112-1 and I/O 112-2) for a respective HBM (HBM 108-1 or HBM 108-2, as illustrated). The overhang architecture is sometimes shortened herein to just “overhang. ” The dedicated I/O may comprise an arrangement of conductive contacts on the lower surface of the overhang and are understood to be electrically coupled to the circuitry of the integrated circuit die (IC 106). In various embodiments, the upper surface of the HBM component is attached and electrically coupled to the conductive contacts of the dedicated input/output (I/O 112-1 and I/O 112-2) on the lower surface of the overhang of IC 106.

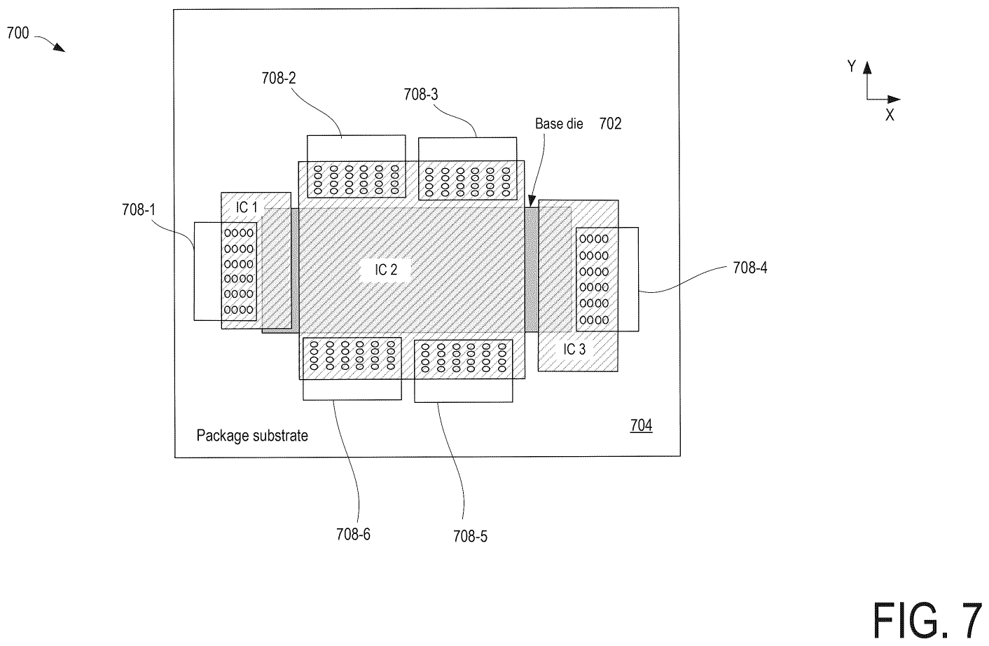

The view 100 depicts a first overhang on the left and a second overhang on the right of the base die 102; however, those with skill in the art will appreciate that other configurations with more or fewer HBM in respective overhangs, as well as more or fewer IC die, may be assembled in accordance with this disclosure (see, e.g., FIG. 7, system in embodiment 700).

In various embodiments, the base die may be attached to a package substrate 104. The package substrate 104/504 enables the components attached on its upper surface to communicate with other dies in an assembly package, such as other dies attached to a motherboard 502 or PCB. In various embodiments, the package substrate 104/504 may comprise a printed circuit board, thin-film substrate, or another suitable substrate.

The cut line A-A′ in view 100 is used to generate the cross-sectional view 130. View 130 illustrates the base die 102 sandwiched between the IC 106 and the package substrate 104, and electrically coupled to both the IC 106 and the package substrate 104. IC 106 is attached to the top surface of the base die 102 with interconnects 132, and bottom surface of the base die 102 is attached to the upper surface of the package substrate with interconnects 140.

As mentioned, the overhang architecture includes conductive contacts that are dedicated input/output (I/O 112-1 and I/O 112-2) for the HBM; in various embodiments, I/O 112-1 and I/O 112-2 are double data rate (DDR) I/O, specifically configured for DDR communication with memory, such as HBM 108-1 and HBM 108-2. In various embodiments, the pitch for the input/output (I/O 112-1 and I/O 112-2) is in a range of 25 microns +/−10% to 90 microns +/−10%, and the width of the interconnects or conductive contacts referred to as I/O 112-1 and I/O 112-2 is 20 microns +/−10% to 35 microns +/−10%.

As shown in FIG. 2, view 200, in various embodiments, HBM 108-1 and HBM 108-2 are memory components that may each be a memory system, comprising multiple memory dies (e.g., memory die 144, memory die 146, memory die 148) stacked and electrically coupled together. The memory dies comprise through silicon vias (TSVs 134); the TSVs provide an electrically conductive path from an upper surface of the respective memory die to the lower surface of the memory die, as illustrated. The TSVs are arranged at a pitch that is associated with an interconnect pitch, described below.

At least two memory dies (in the figure, memory die 144, memory die 146, memory die 148) are attached via their TSVs; attachment is electrical coupling with interconnects 136 (also referred to as HBM microbumps) aligned with TSVs, and the bottom-most memory die, e.g., memory dies 148 in the figure) may be attached and electrically coupled to the package substrate with interconnects 138 (also referred to as HBM flip-chip bumps).

Interconnects are patterned in a desired pinout arrangement that includes dimensions and pitch. In various embodiments, interconnects 132, interconnects 140, interconnects 136, and interconnects 138 may comprise copper (Cu); copper, silver and tin (SnAgCu); tin or lead (Sn or Pb); tin and bismuth (SnBi); or other similar materials. In practice, any of the interconnects 112-1, 112-2, interconnects 132, interconnects 140, interconnects 136, and interconnects 138 may have a diameter of 20 microns +/−10% to 35 microns +/−10% (represented as a width in the X direction in FIG. 1B and FIG. 2, but can be in the Y direction or Z direction as well), and a pitch that is less than 90 microns +/−10%. In various embodiments, the pitch of these interconnects is in a range of about 25 microns and about 90 microns (wherein “about” means +/−10%) and may be referred to as microbumps, C4 flip-chip bumps, or flip-chip bumps. Flip-chip bumps often refer to interconnects that allow an unpackage die to be attached to another (unpackaged) die surface. In various embodiments, as shown in more detail below, a flip-chip bump can have a tiny copper pillar in its center, over which nickel and a combination of tin and silver may be deposited.

The package substrate 104 may be configured with solder bumps 142 on its lower surface. In practice, the solder bumps 142 are interconnects larger than “microbumps,” with a pitch in a range of at least 90 microns to about 150 microns (wherein “about”means +/−10%).

The upper surface 204 of the top-most memory die 144 is to attach to the overhang architecture, specifically, to the dedicated I/O (I/O 112-1 or I/O 112-2) in the overhang. As shown in view 200, in various embodiments, HBM 108-1 and HBM 108-2 have at least one conductive path 202 from the upper surface 204 of the HBM to the bottom surface 206.

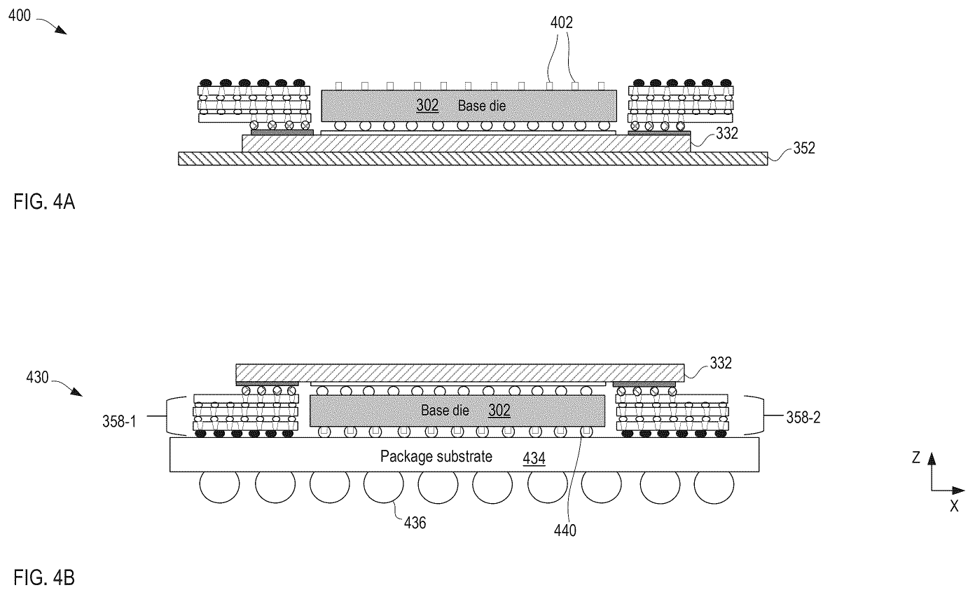

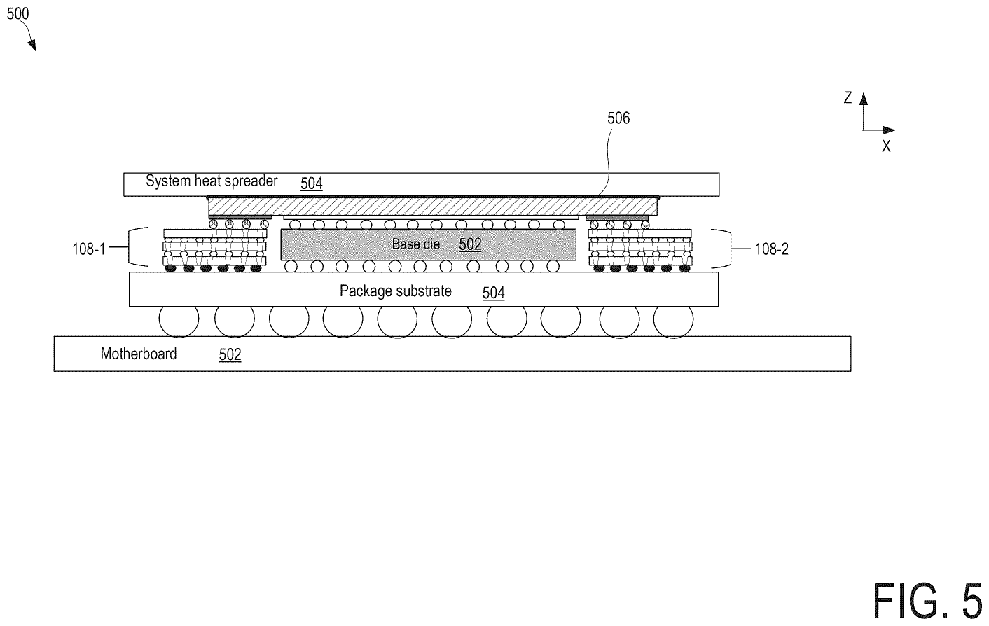

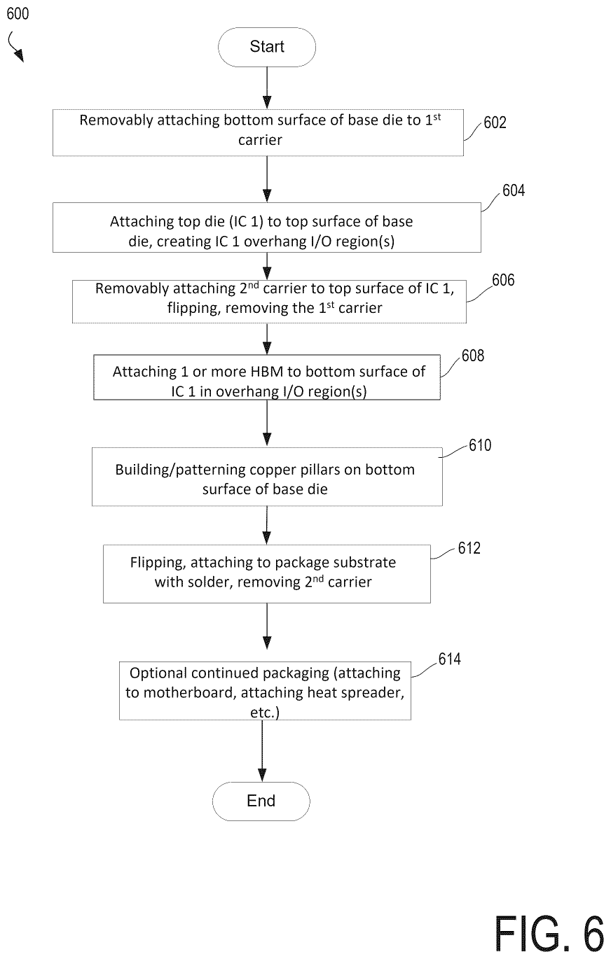

Having described the exemplary overhang architecture, a method for making a system or apparatus with the overhang architecture is now described. FIG. 6 illustrates an example method 600 for manufacturing and assembling various embodiments disclosed herein, and FIGS. 3A, 3B, 3C, 4A, and 4B are simplified illustrations to support FIG. 6, depicting various stages of assembly of exemplary embodiments, as disclosed herein. FIG. 5 depicts an exemplary system, product, or multi-die assembly that can be based on embodiments disclosed herein.

At 602, view 300 depicts the bottom surface of the base die 302 is removably attached to a carrier 304. An adhesive layer (not shown) may be employed to enable the removable attachment. At 604, in view 330, the top die, or IC 332/106 is attached to the top surface of the base die, creating the overhang(s) (represented with width 310) on IC 332/106. The IC 332 may be solder attached with micro-bumps 336/132. As mentioned, the overhang has therein a plurality of conductive contacts, the double data rate (DDR) I/O 334/112, specifically configured for DDR communication with memory. In various embodiments, the task at 604 may be repeated to attach additional IC to the base die, creating additional overhangs.

At 606, in view 350, a second carrier 352 is removably attached to the top surface 335 of the IC 332/106, the component is flipped, and the first carrier 304 is removed.

At 608, one or more HBM (HBM 358-1 and HBM 358-2) memory components are attached or electrically coupled to the overhang architecture at the bottom surface of the top die (IC 332/106), as illustrated and as described above. Electrical coupling is via the interconnects and interconnect material described above. Attachment results in creating at least one electrically coupled path from the DDR I/O 334/112 through the HBM to a flip chip bump on the lower surface of the HBM (e.g., the conductive path 202). In various embodiments that have multiple IC dies with overhangs attached (from 604), the task at 608 may be repeated to add respective HBM memory components.

At 610, view 400, in preparation for flip chip bumps, copper pillars 402 may be patterned or built up on the bottom surface of the base die 302. At 612, view 430, the component created at 610 is flipped and solder-attached or electrically coupled to a package substrate 434 with interconnects (flip chip bumps 440/140). In various embodiments, during solder-attach, the tiny copper pillars 402, may have nickel and a combination of tin and silver (SnAg) deposited thereon. The second carrier 352 is removed.

The view 430 may represent a final product, apparatus, system, or multi-die assembly. In other embodiments, at 614, view 500, the apparatus, system, or multi-die assembly of view 430 may optionally be further assembled or packaged. For example, the component created at 612 may be attached or electrically coupled to a motherboard 502 or printed circuit board (PCB), a heat spreader 504 component may be attached, etc.

A means for thermal management, or system thermal solution may be implemented. The means for thermal management or system thermal solution may include a system heat spreader 504 component, a vapor chamber, a heat pipe, a heat sink, or a liquid-cooled cold plate attached to the multi-die assembly of view 430. The heat spreader 504 component comprises a thermally conductive material. In various embodiments the heat spreader 504 component is metal. In some embodiments, the heat spreader component comprises aluminum. In other embodiments, the heat spreader component may comprise copper.

As part of a system thermal management solution, a thermal conduction layer interface material (TIM) 506 may be located over the IC die and under the system thermal solution. The TIM 506 can be any suitable material, such as a silver particle-filled thermal compound, thermal grease, phase change materials, indium foils, or graphite sheets.

In other embodiments, the system or multi-die assembly of view 430 or view 500 can be overmolded with an encapsulant. The encapsulant can comprise a molding compound, dielectric materials, metal, ceramic, plastic, or a combination thereof.

FIG. 7 is included to illustrate another non-limiting example embodiment 700 that implements the overhang architecture. HBM 708-1, 708-2, 708-3, 708-4, 708-5, 708-6 are analogous to the HBM introduced in FIGS. 1A, 1B, and 2, comprising multiple stacked memory die, electrically coupled, via TSV, and having one or more TSV open at the top surface. IC 1 is shown with the overhang for HBM 708-1; IC 2 is shown with overhang on the top and the bottom of the page, to attach with HBM 708-2, 708-3, 708-5, and 708-6. IC 3 has overhang to attach with HBM 708-4. The base die 702 is underneath IC 1, IC 2, and IC 3. Package substrate 704 is underneath and attached to the base die and the HBM 708-1 through HBM 708-6, as described above.

Thus, the overhang architectures for high bandwidth memory (HBM) multi-die assemblies and methods for making same have been described. Embodiments advantageously provide improved signal integrity performance e.g., reduced signal latency between an IC (e.g., a CPU/SOC (processor)) and the DRAM memory devices through shorter and less distorted signal transmission paths. The signal interconnects between the IC and the DRAM are direct signal interconnects thereby averting signal propagation through lateral routing on a package substrate or on a motherboard. The signal interconnects therefore have reduced signal crosstalk coupling. Additionally, embodiments enable system miniaturization-allowing platform footprint reduction by having smaller package size and smaller base die size through compact placement of the DRAM (HBM) underneath the top IC die.

The practice of embodiments can be confirmed using SEM or TEM images of features, specifically to identify the TSVs on the top side of the HBM, where it is to electrically connect with the dedicated I/O on the overhang of the top IC. One may also look for the flip-chip bumps on the bottom side of the HBM, to connect with the package substrate.

The following description and associated figures provide more detail for components referenced hereinabove.

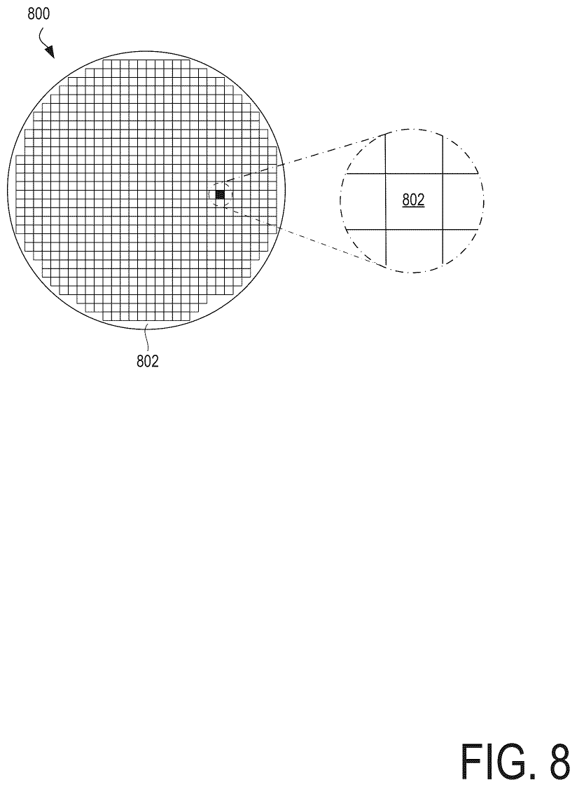

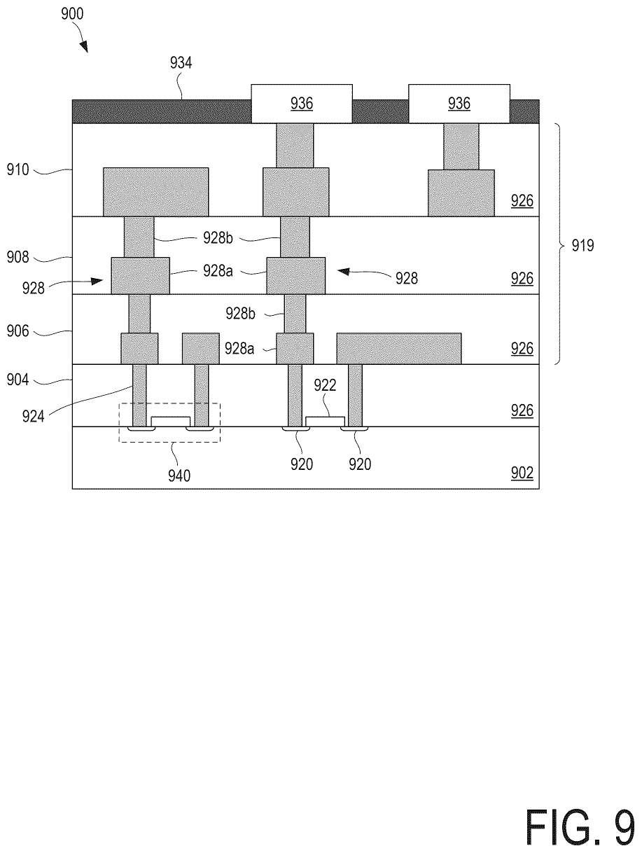

FIG. 8 is a top view of a wafer 800 and dies 802 that may be included in any of the embodiments disclosed herein. The wafer 800 may be composed of semiconductor material and may include one or more dies 802 formed on a surface of the wafer 800. After the fabrication of the integrated circuit components on the wafer 800 is complete, the wafer 800 may undergo a singulation process in which the dies 802 are separated from one another to provide discrete “chips” or destined for a packaged integrated circuit component. The individual dies 802, comprising an integrated circuit component, may include one or more transistors (e.g., some of the transistors 940 of FIG. 9, discussed below), supporting circuitry to route electrical signals to the transistors, passive components (e.g., signal traces, resistors, capacitors, or inductors), and/or any other integrated circuit components. In some embodiments, the wafer 800 or the die 802 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Additionally, multiple devices may be combined on a single die 802. For example, a memory array formed by multiple memory devices may be formed on a same die 802 as a processor unit (e.g., the processor unit 1102 of FIG. 11) or other logic that is configured to store information in the memory devices or execute instructions stored in the memory array. In some embodiments, a die 802 may be attached to a wafer 800 that includes other die, and the wafer 800 is subsequently singulated, this manufacturing procedure is referred to as a die-to-wafer assembly technique.

FIG. 9 is a cross-sectional side view of an integrated circuit 900 that may be included in any of the embodiments disclosed herein. One or more of the integrated circuits 900 may be included in one or more dies 802 (FIG. 8). The integrated circuit 900 may be formed on a die substrate 902 (e.g., the wafer 800 of FIG. 8) and may be included in a die (e.g., the die 802 of FIG. 8).

The die substrate 902 may be a semiconductor substrate composed of semiconductor material systems including, for example, n-type or p-type materials systems (or a combination of both). The die substrate 902 may include, for example, a crystalline substrate formed using a bulk silicon or a silicon-on-insulator (SOI) substructure. In some embodiments, the die substrate 902 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 902. Although a few examples of materials from which the die substrate 902 may be formed are described here, any material that may serve as a foundation for an integrated circuit 900 may be used. The die substrate 902 may be part of a singulated die (e.g., the dies 802 of FIG. 8) or a wafer (e.g., the wafer 800 of FIG. 8).

The integrated circuit 900 may include one or more device layers 904 disposed on the die substrate 902. The device layer 904 may include features of one or more transistors 940 (e.g., metal oxide semiconductor field-effect transistors (MOSFETs)) formed on the die substrate 902. The transistors 940 may include, for example, one or more source and/or drain (S/D) regions 920, a gate 922 to control current flow between the S/D regions 920, and one or more S/D contacts 924 to route electrical signals to/from the S/D regions 920.

The gate 922 may be formed of at least two layers, a gate dielectric and a gate electrode. The gate dielectric may include one layer or a stack of layers. The one or more layers may include silicon oxide, silicon dioxide, silicon carbide, and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be conducted on the gate dielectric to improve its quality when a high-k material is used.

The gate electrode may be formed on the gate dielectric and may include at least one p-type work function metal or n-type work function metal, depending on whether the transistor 940 is to be a p-type metal oxide semiconductor (PMOS) or an n-type metal oxide semiconductor (NMOS) transistor. In some implementations, the gate electrode may comprise a stack of two or more metal layers, where one or more metal layers are work function metal layers and at least one metal layer is a fill metal layer. Further metal layers may be included for other purposes, such as a barrier layer.

For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 940 along the source-channel-drain direction, the gate electrode may comprise a U-shaped structure that includes a bottom portion substantially parallel to the surface of the die substrate 902 and two sidewall portions that are substantially perpendicular to the top surface of the die substrate 902. In other embodiments, at least one of the metal layers that form the gate electrode may simply be a planar layer that is substantially parallel to the top surface of the die substrate 902 and does not include sidewall portions substantially perpendicular to the top surface of the die substrate 902. In other embodiments, the gate electrode may comprise a combination of U-shaped structures and planar, non-U-shaped structures. For example, the gate electrode may comprise one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and include deposition and etching process steps. In some embodiments, a plurality of spacer pairs may be used; for instance, two pairs, three pairs, or four pairs of sidewall spacers may be formed on opposing sides of the gate stack.

The S/D regions 920 may be formed within the die substrate 902 adjacent to the gate 922 of individual transistors 940. The S/D regions 920 may be formed using an implantation/diffusion process or an etching/deposition process, for example. In the former process, dopants such as boron, aluminum, antimony, phosphorous, or arsenic may be ion-implanted into the die substrate 902 to form the S/D regions 920. An annealing process that activates the dopants and causes them to diffuse farther into the die substrate 902 may follow the ion-implantation process. In the latter process, the die substrate 902 may first be etched to form recesses at the locations of the S/D regions 920. An epitaxial deposition process may then be conducted to fill the recesses with material that is used to fabricate the S/D regions 920. In some implementations, the S/D regions 920 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 920 may be formed using one or more alternate semiconductor materials such as germanium or a group III-V material or alloy. In further embodiments, one or more layers of metal and/or metal alloys may be used to form the S/D regions 920.

Electrical signals, such as power and/or input/output (I/O) signals, may be routed to and/or from the devices (e.g., transistors 940) of the device layer 904 through one or more interconnect layers disposed on the device layer 904 (illustrated in FIG. 9 as interconnect layers 906-910). For example, electrically conductive features of the device layer 904 (e.g., the gate 922 and the S/D contacts 924) may be electrically coupled with the interconnect structures 928 of the interconnect layers 906-910. The one or more interconnect layers 906-910 may form a metallization stack (also referred to as an “ILD stack”) 919 of the integrated circuit 900.

The interconnect structures 928 may be arranged within the interconnect layers 906-910 to route electrical signals according to a wide variety of designs; in particular, the arrangement is not limited to the particular configuration of interconnect structures 928 depicted in FIG. 9. Although a particular number of interconnect layers 906-910 is depicted in FIG. 9, embodiments of the present disclosure include integrated circuits having more or fewer interconnect layers than depicted.

In some embodiments, the interconnect structures 928 may include lines 928a and/or vias 928b filled with an electrically conductive material such as a metal. The lines 928a may be arranged to route electrical signals in a direction of a plane that is substantially parallel with a surface of the die substrate 902 upon which the device layer 904 is formed. For example, the lines 928a may route electrical signals in a direction in and out of the page and/or in a direction across the page. The vias 928b may be arranged to route electrical signals in a direction of a plane that is substantially perpendicular to the surface of the die substrate 902 upon which the device layer 904 is formed. In some embodiments, the vias 928b may electrically couple lines 928a of different interconnect layers 906-910 together.

The interconnect layers 906-910 may include a dielectric material 926 disposed between the interconnect structures 928, as shown in FIG. 9. In some embodiments, dielectric material 926 disposed between the interconnect structures 928 in different ones of the interconnect layers 906-910 may have different compositions; in other embodiments, the composition of the dielectric material 926 between different interconnect layers 906-910 may be the same. The device layer 904 may include a dielectric material 926 disposed between the transistors 940 and a bottom layer of the metallization stack as well. The dielectric material 926 included in the device layer 904 may have a different composition than the dielectric material 926 included in the interconnect layers 906-910; in other embodiments, the composition of the dielectric material 926 in the device layer 904 may be the same as a dielectric material 926 included in any one of the interconnect layers 906-910.

A first interconnect layer 906 (referred to as Metal 1 or “M1”) may be formed directly on the device layer 904. In some embodiments, the first interconnect layer 906 may include lines 928a and/or vias 928b, as shown. The lines 928a of the first interconnect layer 906 may be electrically coupled with contacts (e.g., the S/D contacts 924) of the device layer 904. The vias 928b of the first interconnect layer 906 may be coupled with the lines 928a of a second interconnect layer 908.

The second interconnect layer 908 (referred to as Metal 2 or “M2”) may be formed directly on the first interconnect layer 906. In some embodiments, the second interconnect layer 908 may include via 928b to couple the lines 928 of the second interconnect layer 908 with the lines 928a of a third interconnect layer 910. Although the lines 928a and the vias 928b are structurally delineated with a line within individual interconnect layers for the sake of clarity, the lines 928a and the vias 928b may be structurally and/or materially contiguous (e.g., simultaneously filled during a dual-damascene process) in some embodiments.

The third interconnect layer 910 (referred to as Metal 3 or “M3”) (and additional interconnect layers, as desired) may be formed in succession on the second interconnect layer 908 according to similar techniques and configurations described in connection with the second interconnect layer 908 or the first interconnect layer 906. In some embodiments, the interconnect layers that are “higher up” in the metallization stack 919 in the integrated circuit 900 (i.e., farther away from the device layer 904) may be thicker that the interconnect layers that are lower in the metallization stack 919, with lines 928a and vias 928b in the higher interconnect layers being thicker than those in the lower interconnect layers.

The integrated circuit 900 may include a solder resist material 934 (e.g., polyimide or similar material) and one or more conductive contacts 936 formed on the interconnect layers 906-910. In FIG. 9, the conductive contacts 936 are illustrated as taking the form of bond pads. The conductive contacts 936 may be electrically coupled with the interconnect structures 928 and configured to route the electrical signals of the transistor(s) 940 to external devices. For example, solder bonds may be formed on the one or more conductive contacts 936 to mechanically and/or electrically couple an integrated circuit die including the integrated circuit 900 with another component (e.g., a printed circuit board). The integrated circuit 900 may include additional or alternate structures to route the electrical signals from the interconnect layers 906-910; for example, the conductive contacts 936 may include other analogous features (e.g., posts) that route the electrical signals to external components.

In some embodiments in which the integrated circuit 900 is a double-sided die, the integrated circuit 900 may include another metallization stack (not shown) on the opposite side of the device layer(s) 904. This metallization stack may include multiple interconnect layers as discussed above with reference to the interconnect layers 906-910, to provide electrically conductive paths (e.g., including conductive lines and vias) between the device layer(s) 904 and additional conductive contacts (not shown) on the opposite side of the integrated circuit 900 from the conductive contacts 936.

In other embodiments in which the integrated circuit 900 is a double-sided die, the integrated circuit 900 may include one or more through-silicon vias (TSVs) through the die substrate 902; these TSVs may make contact with the device layer(s) 904, and may provide electrically conductive paths between the device layer(s) 904 and additional conductive contacts (not shown) on the opposite side of the integrated circuit 900 from the conductive contacts 936. In some embodiments, TSVs extending through the substrate can be used for routing power and ground signals from conductive contacts on the opposite side of the integrated circuit 900 from the conductive contacts 936 to the transistors 940 and any other components integrated into the integrated circuit 900 die, and the metallization stack 919 can be used to route I/O signals from the conductive contacts 936 to transistors 940 and any other components integrated into the integrated circuit 900 die.

Multiple integrated circuits 900 may be stacked with one or more TSVs in the individual stacked devices providing connection between one of the devices to any of the other devices in the stack. For example, one or more high-bandwidth memory (HBM) integrated circuit dies can be stacked on top of a base integrated circuit die and TSVs in the HBM dies can provide connection between the individual HBM and the base integrated circuit die. Conductive contacts can provide additional connections between adjacent integrated circuit dies in the stack. In some embodiments, the conductive contacts can be fine-pitch solder bumps (microbumps).

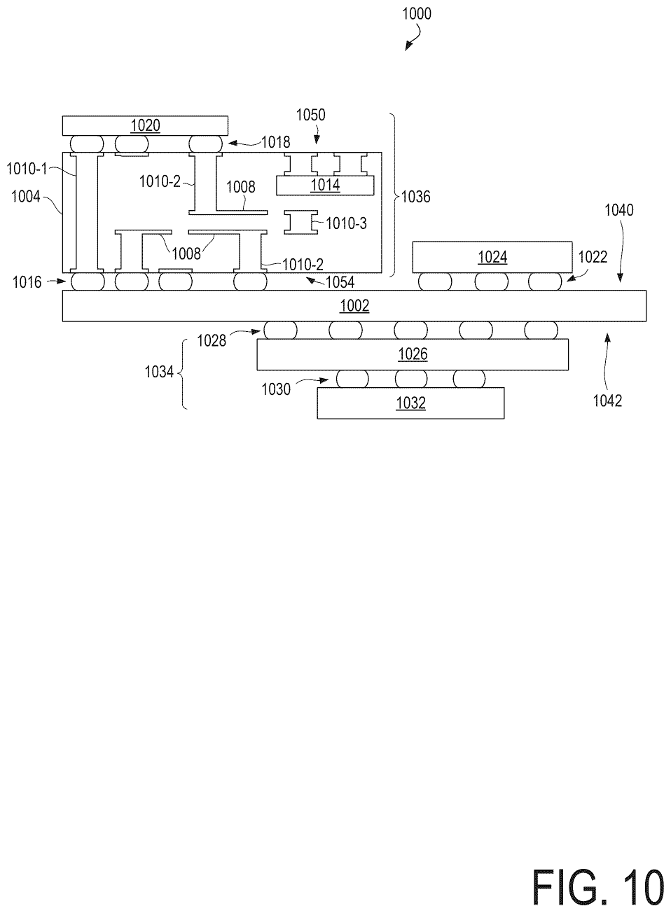

FIG. 10 is a cross-sectional side view of a microelectronic assembly 1000 that may include any of the embodiments disclosed herein. The microelectronic assembly 1000 includes multiple integrated circuit components disposed on a circuit board 1002 (which may be a motherboard, system board, mainboard, etc.). The microelectronic assembly 1000 may include components disposed on a first face 1040 of the circuit board 1002 and an opposing second face 1042 of the circuit board 1002; generally, components may be disposed on one or both faces 1040 and 1042.

In some embodiments, the circuit board 1002 may be a printed circuit board (PCB) including multiple metal (or interconnect) layers separated from one another by layers of dielectric material and interconnected by electrically conductive vias. The individual metal layers comprise conductive traces. Any one or more of the metal layers may be formed in a desired circuit pattern to route electrical signals (optionally in conjunction with other metal layers) between the components coupled to the circuit board 1002. In other embodiments, the circuit board 1002 may be a non-PCB substrate. The microelectronic assembly 1000 illustrated in FIG. 10 includes a package-on-interposer structure 1036 coupled to the first face 1040 of the circuit board 1002 by coupling components 1016. The coupling components 1016 may electrically and mechanically couple the package-on-interposer structure 1036 to the circuit board 1002, and may include solder balls (as shown in FIG. 10), pins (e.g., as part of a pin grid array (PGA), contacts (e.g., as part of a land grid array (LGA)), male and female portions of a socket, an adhesive, an underfill material, and/or any other suitable electrical and/or mechanical coupling structure.

The package-on-interposer structure 1036 may include an integrated circuit component 1020 coupled to an interposer 1004 by coupling components 1018. The coupling components 1018 may take any suitable form for the application, such as the forms discussed above with reference to the coupling components 1016. Although a single integrated circuit component 1020 is shown in FIG. 10, multiple integrated circuit components may be coupled to the interposer 1004; indeed, additional interposers may be coupled to the interposer 1004. The interposer 1004 may provide an intervening substrate used to bridge the circuit board 1002 and the integrated circuit component 1020.

The integrated circuit component 1020 may be a packaged or unpackaged integrated circuit component that includes one or more integrated circuit dies (e.g., the die 802 of FIG. 8, the integrated circuit 900 of FIG. 9) and/or one or more other suitable components.

The unpackaged integrated circuit component 1020 comprises solder bumps attached to contacts on the die. The solder bumps allow the die to be directly attached to the interposer 1004. In embodiments where the integrated circuit component 1020 comprises multiple integrated circuit die, the die can be of the same type (a homogeneous multi-die integrated circuit component) or of two or more different types (a heterogeneous multi-die integrated circuit component). In addition to comprising one or more processor units, the integrated circuit component 1020 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets. ” In embodiments where an integrated circuit component comprises multiple integrated circuit dies, interconnections between dies can be provided by the package substrate, one or more silicon interposers, one or more silicon bridges embedded in the package substrate, or combinations thereof. A packaged multi-die integrated circuit component can be referred to as a multi-chip package (MCP) or multi-chip module (MCM).

The interposer 1004 may spread connections to a wider pitch or reroute a connection to a different connection. For example, the interposer 1004 may couple the integrated circuit component 1020 to a set of ball grid array (BGA) conductive contacts of the coupling components 1016 for coupling to the circuit board 1002. In the embodiment illustrated in FIG. 10, the integrated circuit component 1020 and the circuit board 1002 are attached to opposing sides of the interposer 1004; in other embodiments, the integrated circuit component 1020 and the circuit board 1002 may be attached to a same side of the interposer 1004. In some embodiments, three or more components may be interconnected by way of the interposer 1004.

In some embodiments, the interposer 1004 may be formed as a PCB, including multiple metal layers separated from one another by layers of dielectric material and interconnected by electrically conductive vias. In some embodiments, the interposer 1004 may be formed of an epoxy resin, a fiberglass-reinforced epoxy resin, an epoxy resin with inorganic fillers, a ceramic material, or a polymer material such as polyimide. In some embodiments, the interposer 1004 may be formed of alternate rigid or flexible materials that may include the same materials described above for use in a semiconductor substrate, such as silicon, germanium, and other group III-V and group IV materials. The interposer 1004 may include metal interconnects 1008 and vias 1010, including but not limited to through hole vias 1010-1 (that extend from a first face 1050 of the interposer 1004 to a second face 1054 of the interposer 1004), blind vias 1010-2 (that extend from the first or second faces 1050 or 1054 of the interposer 1004 to an internal metal layer), and buried vias 1010-3 (that connect internal metal layers).

In some embodiments, the interposer 1004 can comprise a silicon interposer. Through-silicon vias (TSV) extending through the silicon interposer can connect connections on the first face of a silicon interposer to an opposing second face of the silicon interposer. In some embodiments, an interposer 1004 comprising a silicon interposer can further comprise one or more routing layers to route connections on a first face of the interposer 1004 to an opposing second face of the interposer 1004.

The interposer 1004 may further include embedded devices 1014, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 1004. The package-on-interposer structure 1036 may take the form of any of the package-on-interposer structures known in the art.

The integrated circuit assembly 1000 may include an integrated circuit component 1024 coupled to the first face 1040 of the circuit board 1002 by coupling components 1022. The coupling components 1022 may take the form of any of the embodiments discussed above with reference to the coupling components 1016, and the integrated circuit component 1024 may take the form of any of the embodiments discussed above with reference to the integrated circuit component 1020.

The integrated circuit assembly 1000 illustrated in FIG. 10 includes a package-on-package structure 1034 coupled to the second face 1042 of the circuit board 1002 by coupling components 1028. The package-on-package structure 1034 may include an integrated circuit component 1026 and an integrated circuit component 1032 coupled together by coupling components 1030 such that the integrated circuit component 1026 is disposed between the circuit board 1002 and the integrated circuit component 1032. The coupling components 1028 and 1030 may take the form of any of the embodiments of the coupling components 1016 discussed above, and the integrated circuit components 1026 and 1032 may take the form of any of the embodiments of the integrated circuit component 1020 discussed above. The package-on-package structure 1034 may be configured in accordance with any of the package-on-package structures known in the art.

FIG. 11 is a block diagram of an example electrical device 1100 that may include one or more of the embodiments disclosed herein. For example, any suitable ones of the components of the electrical device 1100 may include one or more of the multi-die assemblies, package assemblies, microelectronic assemblies 1000, integrated circuit components 1020, integrated circuits 900, integrated circuit dies 802, or structures disclosed herein. A number of components are illustrated in FIG. 11 as included in the electrical device 1100, but any one or more of these components may be omitted or duplicated, as suitable for the application. In some embodiments, some or all the components included in the electrical device 1100 may be attached to one or more motherboards, mainboards, printed circuit boards, or system boards. In some embodiments, one or more of these components are fabricated onto a single system-on-a-chip (SoC) die. In various embodiments, the electrical device 3000 is enclosed by, or integrated with, a housing.

Additionally, in various embodiments, the electrical device 1100 may not include one or more of the components illustrated in FIG. 11, but the electrical device 1100 may include interface circuitry for coupling to the one or more components. For example, the electrical device 1100 may not include a display device 1106, but may include display device interface circuitry (e.g., a connector and driver circuitry) to which a display device 1106 may be coupled. In another set of examples, the electrical device 1100 may not include an audio input device 1124 or an audio output device 1108, but may include audio input or output device interface circuitry (e.g., connectors and supporting circuitry) to which an audio input device 1124 or audio output device 1108 may be coupled.

The electrical device 1100 may include one or more processor units 1102 (e.g., one or more processor units). As used herein, the terms “processor unit,” “processing unit” or “processor” may refer to any device or portion of a device that processes electronic data from registers and/or memory to transform that electronic data into other electronic data that may be stored in registers and/or memory. The processor unit 1102 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller crypto processors (specialized processors that execute cryptographic algorithms within hardware), server processors, controllers, or any other suitable type of processor units. As such, the processor unit can be referred to as an XPU (or xPU).

The electrical device 1100 may include a memory 1104, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 1104 may include memory that is located on the same integrated circuit die as the processor unit 1102. This memory may be used as cache memory (e.g., Level 1 (L1), Level 2 (L2), Level 3 (L3), Level 4 (L4), Last Level Cache (LLC)) and may include embedded dynamic random-access memory (eDRAM) or spin transfer torque magnetic random-access memory (STT-MRAM).

In some embodiments, the electrical device 1100 can comprise one or more processor units 1102 that are heterogeneous or asymmetric to another processor unit 1102 in the electrical device 1100. There can be a variety of differences between the processor units 1102 in a system in terms of a spectrum of metrics of merit including architectural, microarchitectural, thermal, power consumption characteristics, and the like. These differences can effectively manifest themselves as asymmetry and heterogeneity among the processor units 1102 in the electrical device 1100.

In some embodiments, the electrical device 1100 may include a communication component 1112 (e.g., one or more communication components). For example, the communication component 1112 can manage wireless communications for the transfer of data to and from the electrical device 1100. The term “wireless” and its derivatives may be used to describe circuits, devices, systems, methods, techniques, communications channels, etc., that may communicate data using modulated electromagnetic radiation through a nonsolid medium. The term “wireless” does not imply that the associated devices do not contain any wires, although in some embodiments they might not.

The communication component 1112 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra-mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 1112 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 1112 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 1112 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 1112 may operate in accordance with other wireless protocols in other embodiments. The electrical device 1100 may include an antenna 1122 to facilitate wireless communications and/or to receive other wireless communications (such as AM or FM radio transmissions).

In some embodiments, the communication component 1112 may manage wired communications, such as electrical, optical, or any other suitable communication protocols (e.g., IEEE 802.3 Ethernet standards). As noted above, the communication component 1112 may include multiple communication components. For instance, a first communication component 1112 may be dedicated to shorter-range wireless communications such as Wi-Fi or Bluetooth, and a second communication component 1112 may be dedicated to longer-range wireless communications such as global positioning system (GPS), EDGE, GPRS, CDMA, WiMAX, LTE, EV-DO, or others. In some embodiments, a first communication component 1112 may be dedicated to wireless communications, and a second communication component 1112 may be dedicated to wired communications.

The electrical device 1100 may include power supply such as a battery/power circuitry 1114. The battery/power circuitry 1114 may include one or more energy storage devices (e.g., batteries or capacitors) and/or circuitry for coupling components of the electrical device 1100 to an energy source separate from the electrical device 1100 (e.g., AC line power).

The electrical device 1100 may include a display device 1106 (or corresponding interface circuitry, as discussed above). The display device 1106 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 1100 may include an audio output device 1108 (or corresponding interface circuitry, as discussed above). The audio output device 1108 may include any embedded or wired or wirelessly connected external device that generates an audible indicator, such speakers, headsets, or earbuds.

The electrical device 1100 may include an audio input device 1124 (or corresponding interface circuitry, as discussed above). The audio input device 1124 may include any embedded or wired or wirelessly connected device that generates a signal representative of a sound, such as microphones, microphone arrays, or digital instruments (e.g., instruments having a musical instrument digital interface (MIDI) output). The electrical device 1100 may include a Global Navigation Satellite System (GNSS) device 1118 (or corresponding interface circuitry, as discussed above), such as a Global Positioning System (GPS) device. The GNSS device 1118 may be in communication with a satellite-based system and may determine a geolocation of the electrical device 1100 based on information received from one or more GNSS satellites, as known in the art.

The electrical device 1100 may include another output device 1110 (or corresponding interface circuitry, as discussed above). Examples of the other output device 1110 may include an audio codec, a video codec, a printer, a wired or wireless transmitter for providing information to other devices, or an additional storage device.

The electrical device 1100 may include another input device 1120 (or corresponding interface circuitry, as discussed above). Examples of the other input device 1120 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 1100 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra-mobile personal computer, a portable gaming console, etc.), a desktop electrical device, a server, a rack-level computing solution (e.g., blade, tray or sled computing systems), a workstation or other networked computing component, a printer, a scanner, a monitor, a set-top box, an entertainment control unit, a stationary gaming console, smart television, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 1100 may be any other electronic device that processes data. In some embodiments, the electrical device 1100 may comprise multiple discrete physical components. Given the range of devices that the electrical device 1100 can be manifested as in various embodiments, in some embodiments, the electrical device 1100 can be referred to as a computing device or a computing system.

Thus, embodiments of an improved via structure for use with the embedded component have been provided. The provided embodiments advantageously enable the use of finer pitch architectures and high-density input/output (I/O) designs in multi-chip packaging.

While at least one embodiment has been presented in the foregoing detailed description, it should be appreciated that a vast number of variations exist. It should also be appreciated that the disclosed embodiments are only examples, and are not intended to limit the scope, applicability, or configuration of the disclosure in any way. Rather, the foregoing detailed description will provide those skilled in the art with a convenient road map for implementing the disclosed embodiment embodiments. Various changes can be made in the function and arrangement of elements without departing from the scope of the disclosure as set forth in the appended claims and the legal equivalents thereof.

As used herein, phrases such as “an embodiment,” “various embodiments,” “some embodiments,” and the like, indicate that some embodiments may have some, all, or none of the features described for other embodiments. “First,” “second,” “third,” and the like describe a common object and indicate different instances of like objects being referred to; unless specifically stated, they do not imply a given sequence, either temporally or spatially, in ranking, or any other manner. In accordance with patent application parlance, “connected” indicates elements that are in direct physical or electrical contact with each other and “coupled” indicates elements that co-operate or interact with each other, coupled elements may or may not be in direct physical contact. Furthermore, the terms “comprising,” “including,” “having,” and the like, are utilized synonymously to denote non-exclusive inclusions.

As used in this application and the claims, a list of items joined by the term “at least one of” or the term “one or more of” can mean any combination of the listed terms. For example, the phrase “at least one of A, B or C” can mean A; B; C; A and B; A and C; B and C; or A, B, and C. Likewise, the phrase “one or more of A, B and C” can mean A; B; C; A and B; A and C; B and C; or A, B, and C.

As used in this application and the claims, the phrase “individual” and “individual of” or “respective” “respective of” following by a list of items recited or stated as having a trait, feature, etc. means that all the items in the list possess the stated or recited trait, feature, etc. For example, the phrase “individual of A, B, or C, comprise a sidewall” or “respective of A, B, or C, comprise a sidewall” means that A comprises a sidewall, B comprises sidewall, and C comprises a sidewall.

Theories of operation, scientific principles, or other theoretical descriptions presented herein in reference to the apparatuses or methods of this disclosure have been provided for the purposes of better understanding and are not intended to be limiting in scope. The apparatuses and methods in the appended claims are not limited to those apparatuses and methods that function in the manner described by such theories of operation.

The following examples pertain to additional embodiments of technologies disclosed herein.

### EXAMPLES

Example 1 is an apparatus, comprising: a first memory die comprising a top surface and a bottom surface, the first memory die having a plurality of TSVs (through silicon vias) extending from the top surface to the bottom surface; and a second memory die having an upper surface and a lower surface, the lower surface of the second memory die is electrically coupled to the top surface of the first memory die via the plurality of TSVs; wherein the second memory die further comprises at least one TSV extending from the upper surface to the lower surface.

Example 2 includes the subject matter of Example 1, wherein the TSVs are arranged at a pitch that is less than 90 microns, plus or minus 10%.

Example 3 includes the subject matter of Example 1, wherein individual TSVs of the plurality of TSVs have a respective interconnect attached on the bottom surface.

Example 4includes the subject matter of any one of Examples 1-3, wherein the second memory die is attached to the first memory die via a respective interconnect aligned with individual TSVs of the plurality of TSVs.

Example 5 includes the subject matter of Example 4, wherein the interconnects comprise copper, silver, lead or tin.

Example 6 is a multi-die assembly comprising: a base die having a top surface and a bottom surface; an integrated circuit (IC) die attached to the top surface of the base die, the IC die including an overhang, defined as an extension of the IC die past an external periphery of the base die; an arrangement of conductive contacts on a lower surface of the overhang; and a memory component below the overhang, attached to the arrangement of conductive contacts.

Example 7 includes the subject matter of Example 6, wherein the memory component comprises at least one TSV on its upper surface, the at least one TSV is electrically coupled to a conductive contact on the lower surface of the overhang.

Example 8 includes the subject matter of Example 6 or Example 7, wherein the memory component comprises at least one electrically conductive path from a conductive contact on the lower surface of the overhang to a bottom of the memory component.

Example 9 includes the subject matter of any one of Examples 6-8, wherein the memory component comprises: a first memory die comprising a first surface and a second surface, the first memory die having a plurality of TSVs (through silicon vias) extending from the first surface to the second surface; and a second memory die having third surface and a fourth surface, the fourth surface of the second memory die is attached to the first surface of the first memory die via the plurality of TSVs; wherein the second memory die comprises at least one TSV extending from the third surface to the fourth surface.

Example 10 includes the subject matter of Example 9, wherein individual TSVs of the plurality of TSVs have a respective interconnect attached on the bottom surface.

Example 11 includes the subject matter of Example 9, wherein the second memory die is attached to the first memory die via a respective interconnect aligned with individual TSVs of the plurality of TSVs.

Example 12 includes the subject matter of Example 11, wherein the interconnects comprise copper, silver, lead, or tin.

Example 13 includes the subject matter of Example 11, wherein the IC die is a central processing unit (CPU) or system on chip (SOC).

Example 14 includes the subject matter of Example 6, wherein the overhang is a first overhang, the arrangement is a first arrangement, the memory component is a first memory component, and further comprising: a second overhang; a second arrangement of the conductive contacts on a lower surface of the second overhang; and a second memory component below the second overhang, attached to the second arrangement of conductive contacts.

Example 15 includes the subject matter of Example 6, further comprising a second IC die attached to the base die.

Example 16 includes the subject matter of Example 6, further comprising: a package substrate having solder bumps on a first side; wherein the base die and the memory component are adjacent and attached on an opposite side of the package substrate; and at least one conductive path from the memory component to a solder bump.

Example 17 is a method, comprising: attaching an integrated circuit (IC) die to a base die; wherein the IC die has an overhang, defined as an extension beyond an external periphery of the base die; and wherein the overhang comprises an arrangement of conductive contacts on a lower surface of the overhang.

Example 18 includes the subject matter of Example 17, further comprising: attaching a memory component to the conductive contacts, wherein attaching comprises electrically coupling via interconnects.

Example 19 includes the subject matter of Example 18, further comprising: patterning copper pillars on a bottom surface of the base die; attaching the memory component to the base die via interconnects; and attaching the base die to a package substrate via the copper pillars.

Example 20 includes the subject matter of Example 17, further comprising: attaching an additional integrated circuit (IC) die to the base die; wherein the additional IC die has an additional overhang; and wherein the additional overhang comprises an additional arrangement of conductive contacts on a lower surface of the additional overhang.

What is claimed is:

1. An apparatus, comprising:
a base die having a top surface and a bottom surface;
an integrated circuit (IC) die attached to the top surface of the base die, the IC die including an overhang, defined as an extension of the IC die past an external periphery of the base die;
an arrangement of conductive contacts on a lower surface of the overhang; and
a memory component below the overhang, attached to the arrangement of conductive contacts.

2. The apparatus of claim 1, wherein the memory component comprises:
a first memory die comprising a top surface and a bottom surface, the first memory die having a plurality of TSVs (through silicon vias) extending from the top surface to the bottom surface; and
a second memory die having an upper surface and a lower surface, the lower surface of the second memory die is electrically coupled to the top surface of the first memory die via the plurality of TSVs;
wherein the second memory die further comprises at least one TSV electrically coupled to a conductive contact and extending from the upper surface to the lower surface.

3. The apparatus of claim 2, wherein the TSVs are arranged at a pitch that is less than 90 microns, plus or minus 10%.

4. The apparatus of claim 2, wherein individual TSVs of the plurality of TSVs have a respective interconnect attached on the bottom surface.

5. The apparatus of claim 2, wherein the second memory die is attached to the first memory die via a respective interconnect aligned with individual TSVs of the plurality of TSVs.

6. A multi-die assembly comprising:
a first integrated circuit (IC) die;
a second IC die vertically over the first IC die, the second IC die including an overhanging portion that extends horizontally beyond a horizontal extent of the first IC die;
an arrangement of conductive contacts on a lower surface of the overhanging portion of the second IC die; and
a memory component horizontally adjacent to the first IC die and vertically below the overhanging portion of the second IC die, the memory component attached to the arrangement of conductive contacts.

7. The multi-die assembly of claim 6, wherein the memory component comprises at least one TSV on its upper surface, the at least one TSV is electrically coupled to a conductive contact on the lower surface of the overhanging portion.

8. The multi-die assembly of claim 6, wherein the memory component comprises at least one electrically conductive path from a conductive contact on the lower surface of the overhanging portion to a bottom of the memory component.

9. The multi-die assembly of claim 6, wherein the memory component comprises:
a first memory die comprising a first surface and a second surface, the first memory die having a plurality of TSVs (through silicon vias) extending from the first surface to the second surface; and
a second memory die having third surface and a fourth surface, the fourth surface of the second memory die is attached to the first surface of the first memory die via the plurality of TSVs;
wherein the second memory die comprises at least one TSV extending from the third surface to the fourth surface.

10. The multi-die assembly of claim 9, wherein individual TSVs of the plurality of TSVs have a respective interconnect attached on the first surface.

11. The multi-die assembly of claim 9, wherein the second memory die is attached to the first memory die via a respective interconnect aligned with individual TSVs of the plurality of TSVs.

12. The multi-die assembly of claim 11, wherein the interconnects comprise copper, silver, lead, or tin.

13. The multi-die assembly of claim 11, wherein the IC die is a central processing unit (CPU) or system on chip (SOC).

14. The multi-die assembly of claim 6, wherein the overhang is a first overhang, the arrangement is a first arrangement, the memory component is a first memory component, and further comprising:
a second overhang;
a second arrangement of the conductive contacts on a lower surface of the second overhang; and
a second memory component below the second overhang, attached to the second arrangement of conductive contacts.

15. The multi-die assembly of claim 6, further comprising a second IC die attached to the first IC die.

16. The multi-die assembly of claim 6, further comprising:
a package substrate having solder bumps on a first side;
wherein the first IC die and the memory component are adjacent and attached on an opposite side of the package substrate; and
at least one conductive path from the memory component to a solder bump.

17. A method, comprising:
attaching an integrated circuit (IC) die to a base die; and
wherein the IC die has an overhang, defined as an extension beyond an external periphery of the base die;
wherein the overhang comprises an arrangement of conductive contacts on a lower surface of the overhang.

18. The method of claim 17, further comprising: attaching a memory component to the conductive contacts, wherein attaching comprises electrically coupling via interconnects.

19. The method of claim 18, further comprising:
patterning copper pillars on a bottom surface of the base die;
attaching the memory component to the base die via interconnects; and
attaching the base die to a package substrate via the copper pillars.

20. The method of claim 17, further comprising:
attaching an additional integrated circuit (IC) die to the base die; and
wherein the additional IC die has an additional overhang;
wherein the additional overhang comprises an additional arrangement of conductive contacts on a lower surface of the additional overhang.
